(19) United States
(12) Patent Application Publication
(10) Pub. No.: US 2024/0340014 A1
(43) Pub. Date: Oct. 10, 2024

(54) CIRCUIT ARRANGEMENT, TIME-MODE ARITHMETIC UNIT, ALL-DIGITAL PHASE-LOCKED LOOP, AND CORRESPONDING METHODS

(71) Applicants: Sony Semiconductor Solutions Corporation, Atsugi-shi, Kanagawa (JP); SONY EUROPE B.V., Weybridge Surrey (DE)

(72) Inventors: Zhong GAO, Delft (NL); Masoud BABAIE, Delft (NL); Martin FRITZ, Stuttgart (DE); Jingchu HE, Delft (NL); Morteza ALAVI, Delft (NL); Bogdan STASZEWSKI, Delft (NL)

(73) Assignees: Sony Semiconductor Solutions Corporation, Atsugi-shi, Kanagawa (JP); SONY EUROPE B.V., Weybridge Surrey (DE)

(21) Appl. No.: 18/293,368

(22) PCT Filed: Aug. 5, 2022
(86) PCT No.: PCT/EP2022/072116

§ 371 Date: Jan. 30, 2024

(30) Foreign Application Priority Data
Aug. 6, 2021 (EP) 21190043.6

(51) Int. Cl. H03L 7/081; H03L 7/089; H03L 7/093

(52) U.S. Cl. CPC H03L 7/0814; H03L 7/0816; H03L 7/0891; H03L 7/093

(57) ABSTRACT

Examples relate to a circuit arrangement, a time-mode arithmetic unit circuit arrangement, an all-digital phase-locked loop, and corresponding methods. A circuit arrangement is configured to discard charges from a capacitive circuit element of the circuit arrangement based on a width of one or more signal pulses of an input signal being provided to the circuit arrangement, with the rate at which the charges are discarded being dependent on at least one control signal being provided to the circuit arrangement. The circuit arrangement is configured to provide an output signal flank having a delay relative to a readout signal flank being provided to the circuit arrangement, with the delay being based on the charges stored in the capacitive circuit element at the time the readout signal flank is provided to the circuit arrangement.

### FIELD

Examples relate to a circuit arrangement, a time-mode arithmetic unit circuit arrangement, an all-digital phase-locked loop, and corresponding methods.

### BACKGROUND

There are various types of circuits. For example, voltage-mode circuits (VMC) and current-mode circuits (CMC) operate on voltages or currents, respectively. Another type of circuit is the time-mode circuit (TMC), which operates on signal edges, i.e., time-mode signals.

### SUMMARY

There may be a desire for providing circuitry for performing operations on time-mode signals.

This desire is addressed by the subject-matter of the independent claims.

Examples of the present disclosure relate to a Time-mode Arithmetic Unit (TAU) circuit arrangement with applications in an All-Digital Phase-Locked Loop (ADPLL), to a component of the TAU circuit arrangement, to an ADPLL circuit arrangement comprising the TAU circuit arrangement, and to corresponding methods. In particular, examples of the present disclosure provide a concept for performing weighted operations on time-mode signals using a circuit arrangement that is based on discharging a capacitive circuit element. The rate at which the capacitive circuit element is being discharged can be varied according to a control signal, thereby enabling the weighted operations on the time-mode signals. For example, the proposed concept can be implemented by successively discharging a capacitive circuit element, e.g., via a resistor, and tuning the RC time constant.

Some examples of the present disclosure relate to a circuit arrangement. The circuit arrangement is configured to discard charges from a capacitive circuit element of the circuit arrangement based on a width of one or more signal pulses of an input signal being provided to the circuit arrangement. The rate at which the charges are discarded is dependent on at least one control signal being provided to the circuit arrangement. The circuit arrangement is configured to provide an output signal flank having a delay relative to a readout signal flank being provided to the circuit arrangement. The delay is based on the charges stored in the capacitive circuit element at the time the readout signal flank is provided to the circuit arrangement. By providing the output of the circuit arrangement in terms of a signal flank being based on a delay relative to a trigger (i.e., the readout signal flank), the output of the circuit arrangement may be used in time-mode circuits. Furthermore, by providing means for varying the discharge rate, weighted operations can be implemented for use in time-mode circuits. This may enable a more wide-ranging adaptation of time-mode circuits, which may provide improvements with regards to PVT (Process Voltage Temperature) sensitivity.

In the following, an example of an implementation of the above circuit arrangement is given. Some examples relate to a circuit arrangement comprising a capacitive circuit element, a resistive circuit element, and an output circuit element. The circuit arrangement is configured to discard charges from the capacitive circuit element via the resistive circuit element based on a width of one or more signal pulses of an input signal being provided to the circuit arrangement. The rate at which the charges are discarded via the resistive circuit element are dependent on at least one control signal being provided to the circuit arrangement to control at least one of a capacitance of the capacitive circuit element and an electrical resistance of the resistive circuit element. The output circuit element is configured to provide an output signal flank having a delay relative to a readout signal flank being provided to the circuit arrangement, with the delay being based on the charges stored in the capacitive circuit element at the time the readout signal flank is provided to the circuit arrangement. By varying at least one of the capacitance of the capacitive circuit element and the electrical resistance of the resistive circuit element, the rate of discharge may be varied. The output circuit element may be used to trigger the output signal flank, which in turn can be used as to generate a time-mode signal. For example, a capacitance of the capacitive circuit element and/or an electrical resistance of the resistive circuit element may be adjusted to vary the rate at which the charges are discarded from the capacitive circuit element, thereby enabling weighted time-mode operations.

Some examples of the present disclosure relate to TAU circuit arrangement. The TAU circuit arrangement comprises at least a first and a second circuit arrangement as introduced above. The TAU circuit arrangement comprises control circuitry configured to convert a time-mode input signal comprising at least a first pair of input signal flanks to a first and a second input signal. The first and second input signal each comprise at least a first signal pulse having a pulse width being based on a delay between the flanks of the first pair of input signal flanks. The control circuitry is configured to provide the first and second input signal to the first and second circuit arrangement. The control circuitry is configured to provide a time-mode output signal comprising a pair of output signal flanks based on respective output signals of the first and second circuit arrangements. By converting the time-mode input signal to pulse widths for the respective circuit arrangements, a time-mode input signal may be used to drive the circuit arrangement outlined above. By using at least two circuit arrangements, as outlined above, a time-mode output signal can be generated that is based on the delay between the output signal flanks of the two output signals of the circuit arrangements. For example, the proposed TAU circuit arrangement may be used in an ADPLL, be used to implement a Finite Impulse Response (FIR) filter, or to implement a time amplification, at a low implementation complexity and with a low sensitivity with respect to PVT variations.

Some examples relate to an ADPLL circuit arrangement comprising the TAU circuit arrangement outlined above. For example, in an ADPLL, the TAU circuit arrangement can be used to capture an offset between an oscillator signal and a signal flank of a reference signal, and to scale the offset for quantization by a Time-to-Digital converter (TDC).

Some examples relate to corresponding methods. Features described in connection with the circuit arrangement outlined above may be likewise included in the corresponding methods.

Some examples relate to a method for operating a circuit arrangement. The method comprises discarding charges from a capacitive circuit element of the circuit arrangement based on a width of one or more signal pulses of an input signal being provided to the circuit arrangement. The rate at which the charges are discarded is dependent on at least one control signal being provided to the circuit arrangement. The method comprises providing an output signal flank having a delay relative to a readout signal flank being provided to the circuit arrangement. The delay is based on the charges stored in the capacitive circuit element at the time the readout signal flank is provided to the circuit arrangement.

Some examples relate to a method for operating a TAU circuit arrangement. The method comprises converting a time-mode input signal comprising at least a first pair of input signal flanks to a first and a second input signal. The first and second input signals each comprise at least a first signal pulse having a pulse width being based on a delay between the flanks of the first pair of input signal flanks. The method comprises discarding charges from a first capacitive circuit element based on a width of at least the first pulse of the first input signal. The method comprises discarding charges from a second capacitive circuit element based on a width of at least the first pulse of the second input signal. The method comprises providing a flank of a pair of output signal flanks having a delay relative to a readout signal flank. The delay is based on the charges stored in the first capacitive circuit element at the time the readout signal flank is provided. The method comprises providing the other flank of the pair of output signal flanks having a delay relative to the readout signal flank. The delay is based on the charges stored in the second capacitive circuit element at the time the readout signal flank is provided. The method comprises providing a time-mode output signal comprising the pair of output signal flanks.

### BRIEF DESCRIPTION OF THE FIGURES

Some examples of apparatuses and/or methods will be described in the following by way of example only, and with reference to the accompanying figures, in which

FIG. 1a shows a schematic diagram of an example of a voltage-mode circuit;

FIG. 1b shows a schematic diagram of an example of a current-mode circuit;

FIG. 1c shows a schematic diagram of an example of a time-mode circuit;

FIG. 2 shows a schematic diagram of an example of a path-selection digital-to-time-converter;

FIG. 3a shows a schematic diagram of an example of a simplified model of a time register;

FIG. 3b shows a diagram of an example of a waveform for a time register;

FIGS. 4a and 4b show block diagrams of examples of a circuit arrangement;

FIG. 5a shows a schematic diagram of an example of a circuit arrangement denoted successive discharge unit (SDU);

FIG. 5b shows a diagram of an example of a waveform of an SDU;

FIGS. 6a and 6b shows block diagrams of example of a TAU circuit arrangement;

FIG. 7a shows a schematic diagram of an example of a TAU circuit arrangement;

FIG. 7b shows a diagram of an example of a waveform of a TAU;

FIGS. 8 and 9 show schematic diagrams of examples of ADPLLs comprising a TAU circuit arrangement;

FIG. 10 shows a flow chart of an example of a method for operating a circuit arrangement; and

FIG. 11 shows a flow chart of an example of a method for operating a TAU circuit arrangement.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an ‘or’, this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

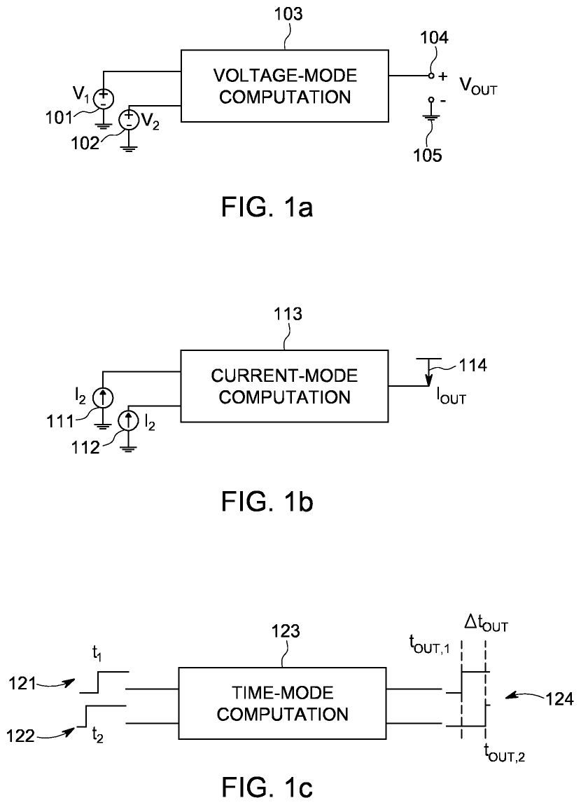

Two of the most-used types of circuits are so-called voltage-mode circuits (VMC) and current-mode circuits (CMC), which operate on voltages or currents, respectively. Another type of circuits is the time-mode circuit (TMC), which operates on signal edges, i.e., time-mode signals. FIGS. 1a to 1c show schematic examples of such circuits.

FIG. 1a shows a schematic diagram of an example of a voltage-mode circuit. In FIG. 1a, two voltage sources 101; 102 are shown, providing voltages V₁ and V₂, respectively. The voltages are provided to a voltage-mode computation circuit 103, with the result being provided at a terminal 104 as voltage V_{OUT} relative to a (ground) potential 105.

FIG. 1b shows a schematic diagram of an example of a current-mode circuit. In FIG. 1b, two current sources 111; 112 are shown, providing currents I₁ and I₂. The currents are provided to a current-mode computation circuit 113, with the result being provided as current I_{OUT} at a terminal 114.

FIG. 1c shows a schematic diagram of an example of a time-mode circuit. In the time-mode circuit of FIG. 1c, two signal flanks (i.e., signal edges) 121; 122 at time t₁ and t₂ are provided as input to the time-mode computation circuit 123. The result is provided as a time difference Δt_{OUT} 124 between two signal edges t_{OUT,1}, t_{OUT,2}, i.e., the output signal, which is provided via two signal components, contains the result in differential form.

Since TMCs do not operate on signal swings, it is claimed in the literature that TMCs can avoid the SNR (Signal-to-Noise-Ratio) degradation of VMCs and CMCs, due to smaller voltage swings of shrinking CMOS (Complementary Metal-Oxide-Semiconductor) process technology. Therefore, TMCs have gained significant attention in academia. However, some of the performance gains may be lost during conversion between voltage mode/current mode signals and time-mode signals. Moreover, compared to VMC and CMC, TMC design is still in its infancy, and several basic operations are still missing. This can be seen both on the system level and block level.

On the system level, VMC and CMC typically employ some analog circuits prior to quantization circuits to relax ADC (Analog-to-Digital Converter) requirements and to improve or optimize the overall system. For example, variable gain amplifiers (VGAs) may be used to fit the amplitude of an input signal to a dynamic range of the ADC; filters may be employed to reject undesired signals, thus preventing ADC saturation, or mixers may be exploited to reduce ADC sampling frequency. However, these kinds of circuits are not yet known in the case of TMC. Consequently, high dynamic range requirements and high-resolution requirements may be simultaneously imposed on the time to digital conversion (TDC).

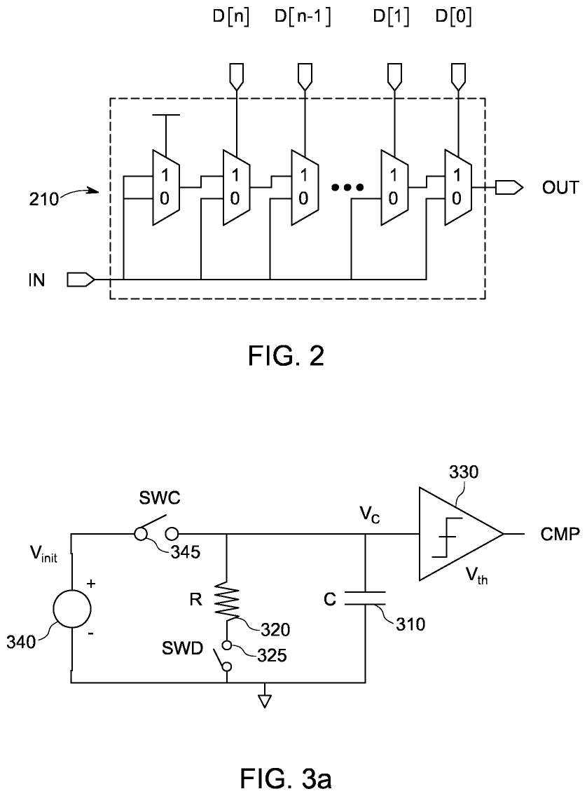

On a block level (i.e., on a level of abstraction above the circuit being used for implementation), the existing time-mode signal generation solutions, which vary the time difference between certain events, are often sensitive to PVT (Process Voltage Temperature) or complex to be implemented on-chip efficiently. For instance, a path-selection DTC, as shown in FIG. 2 is a convenient way to generate time-mode signals. FIG. 2 shows a schematic diagram of an example of a path-selection digital-to-time-converter. The path-selection DTC comprises an input (IN), an output (OUT), a plurality of multiplexers (MUX, 210), and inputs for control signals D[0]-D[n]. A different magnitude of the time-mode signal, delay, can be derived by varying the number of MUXs 210 in the path from IN to OUT via the control signals D[0]-D[n]. However, this approach relies on the physical parameters of devices, e.g., delay of MUXs, thus resulting in DTC's sensitivity to PVT, which is the culprit of many issues. For instance, the DTC delay generated by the same code may vary depending on the power supply or temperature, thus degrading DTC linearity. While generating the output, a DTC inevitably imposes a code-dependent ripple on its power supply, which may not recover before the next cycle. Due to the sensitivity to the supply voltage, DTC output in the next cycle may be affected, which indicates a memory effect. Such a memory effect may degrade DTC dynamic linearity. To tackle these issues, extra efforts may be done on the system level, like delay calibration, supply isolation or DLL (Delay Locked Loop) stabilization, increasing overall system complexity and power consumption. Some of the PVT problems can be solved by calibration. However, calibration is limited and typically slow, for example multiple 100 μs. Moreover, if strong non-linearities are present, calibration might be problematic.

In the following, an implementation for universal Time-mode Arithmetic Unit (TAU) is proposed, which may overcome the limitations outlined above. The main function of a TAU may include registering, calculating, and outputting a (weighted) sum of input time differences. For example, the transfer function of TAU may be defined as

$$Δ {t}_{out} = {\sum }_{i = 1}^{n} {w}_{i} Δ {t}_{i} , \qquad ( 1 )$$

where wᵢ and Δtᵢ are the weight and value of the i-th input time difference, respectively, and Δtₒᵤₜ is the output time difference. In general, the coefficients wᵢ can also be chosen in a way that a common scaling factor of the whole weighted sum is realized, which represents a time amplification (TA). For the case n=1 (i.e., a single summand), a TAU may realize a pure time-mode signal amplification. In the case of time amplification, with n=1, this means that the output time may be just related to the current input time and not to previous samples, and w₁ may be the amplification factor.

Currently, a full implementation of a TAU has not been reported in the literature The use of individual weights in the time register, i.e. that each summand can have its individual coefficient, may be considered a major improvement provided by various examples of the present disclosure. In the following, first, the principle of a time register will be introduced, followed by a circuit arrangement that can be used to implement a time register with individual weights.

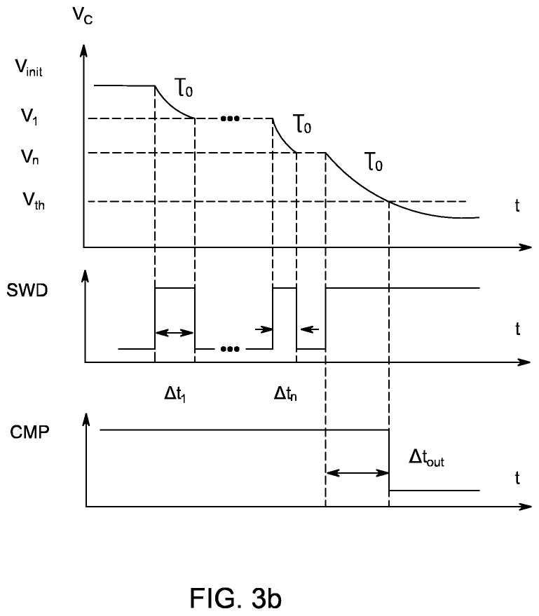

To illustrate the underlying concept being used in a TAU, a simplified RC model and its waveform for one complete write and read cycle are shown in FIGS. 3a and 3b, respectively. FIG. 3a shows a schematic diagram of an example of a simplified model of a time register. FIG. 3b shows a diagram of an example of a waveform for a time register. The simplified circuit shown in FIG. 3a comprises a capacitor C 310, a resistor R 320, a first switch 325 being controlled via signal SWD, a comparator 330, a voltage source 340 and a second switch 345 being controlled via signal SWC. The voltage source has a + terminal and a − terminal, providing a voltage Vᵢₙᵢₜ at the + terminal, with the − terminal being tied to a ground potential. A first terminal of the second switch 345 is coupled to the + terminal of the voltage source 340. A second terminal of the second switch 345 is coupled to a first terminal of the resistor 320, to a first terminal of the capacitor 310, and to an input terminal of the comparator, carrying a voltage V_{c}. The second terminal of the resistor 320 is tied to ground via the first switch 325. The second terminal of the capacitor 310 is tied to ground.

The capacitor C 310 is initially charged to Vᵢₙᵢₜ (shown in FIG. 3b). Then an input pulse turns on the first switch 325 (SWD) to discharge C. As a result, the voltage, V_{c}, changes by an amount (shown in FIG. 3b), determined by the duration of the discharge pulse, as shown in FIG. 3b (Δt₁, . . . , Δtᵢ, . . . , Δtₙ). Then this process can be repeated by an arbitrary number of discharge pulses, e.g., n times, to discharge C. The total amount of V_{c} change is determined by the sum of all Δtᵢ. In other words, the input pulses convert and accumulate themselves as a voltage on C (V_{c}). When the stored time is to be read-out, SWD needs to be ON until V_{C} falls below a threshold voltage (Vₜₕ) of the output buffer/comparator 330 and the falling edge of the CMP is triggered. The output time-mode signal (Δtₒᵤₜ) provided by the comparator is the time difference between the last SWD rising edge and CMP falling edge (shown in FIG. 3b). Mathematical analysis shows

$$Δ {t}_{out} = RC ln ( \frac{{V}_{init}}{{V}_{th}} ) - {\sum }_{i = 1}^{n} Δ {t}_{i} , \qquad ( 2 )$$

where

$$RC ln ( \frac{{V}_{init}}{{V}_{th}} )$$

is the constant output offset and Δtᵢ is the pulse duration of the ith input signal. In the example of FIG. 3a, an RC constant τ of the capacitor and resistor is the same for each discharge.

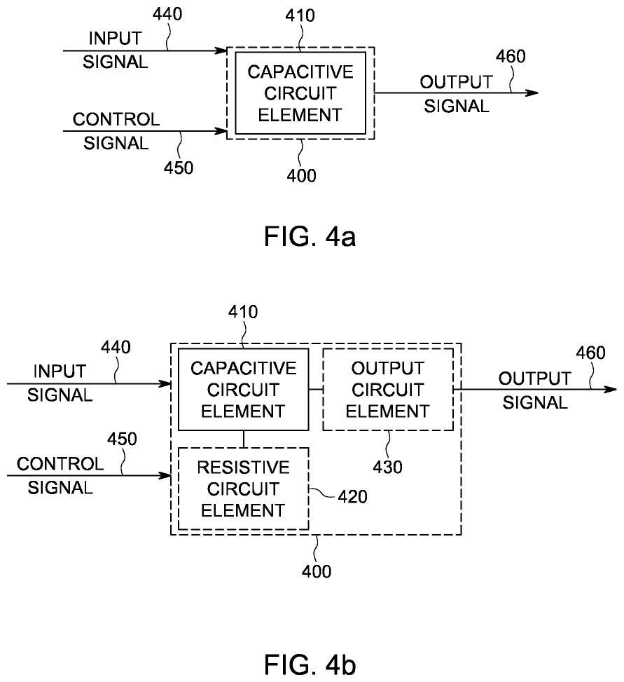

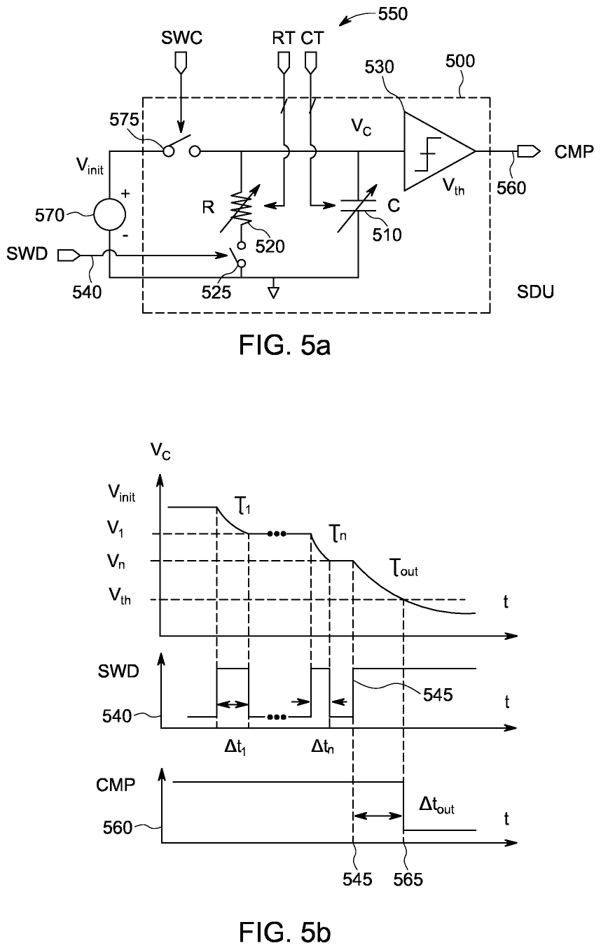

The time register shown in FIG. 3a has the same weight for all input pulses, since R and C remain constant during the operation. In the following, a time-register with variable weights for different input pulses is introduced. Such a time-register is shown in FIGS. 4a to 5a, with corresponding waveforms being shown in FIG. 5b.

The proposed time-register, in the following also denoted Successive Discharge Unit (SDU) or circuit arrangement, is based on the insight that, if R and C become tuneable, the RC-time-constant τ=R·C can be varied. More generally, the concept is based on the insight, that the rate of discharge of the capacitor can be varied to enable a time-register supporting variable weights. This, in turn, enables a TAU to realize individual weights for each summand, i.e., per discharge pulse duration. The schematic and waveform of this component, SDU, are shown in FIGS. 4a-5a and FIG. 5b, respectively. In various examples the output time difference becomes

$$Δ {t}_{out} = {τ}_{out} ln ( \frac{{V}_{init}}{{V}_{th}} ) - {\sum }_{i = 1}^{n} \frac{{τ}_{out}}{{τ}_{i}} Δ {t}_{i} , \qquad ( 3 )$$

from which the weights for each pulse,

$$\frac{{τ}_{o u t}}{{τ}_{i}} ,$$

can be easily observed. The constant terms Vᵢₙᵢₜ and Vₜₕ relate to the supply/initial voltage being used to charge the capacitor, and to the threshold voltage, respectively

FIGS. 4a and 4b show block diagrams of examples of a circuit arrangement 400. The circuit arrangement 400 comprises at least a capacitive circuit element 410, which may comprise a capacitor or bank of capacitors (i.e., a plurality of capacitors being selectively connected in parallel via control circuitry), and further circuitry for controlling a charging and discharging of charges to and from the capacitive circuit element 410. The circuit arrangement is configured to discard charges from the capacitive circuit element 410 based on a width of one or more signal pulses of an input signal 440 being provided to the circuit arrangement. The rate at which the charges are discarded is dependent on at least one control signal 450 being provided to the circuit arrangement. The circuit arrangement is configured to provide an output signal flank having a delay relative to a readout signal flank being provided to the circuit arrangement. The delay is based on the charges stored in the capacitive circuit element at the time the readout signal flank is provided to the circuit arrangement.

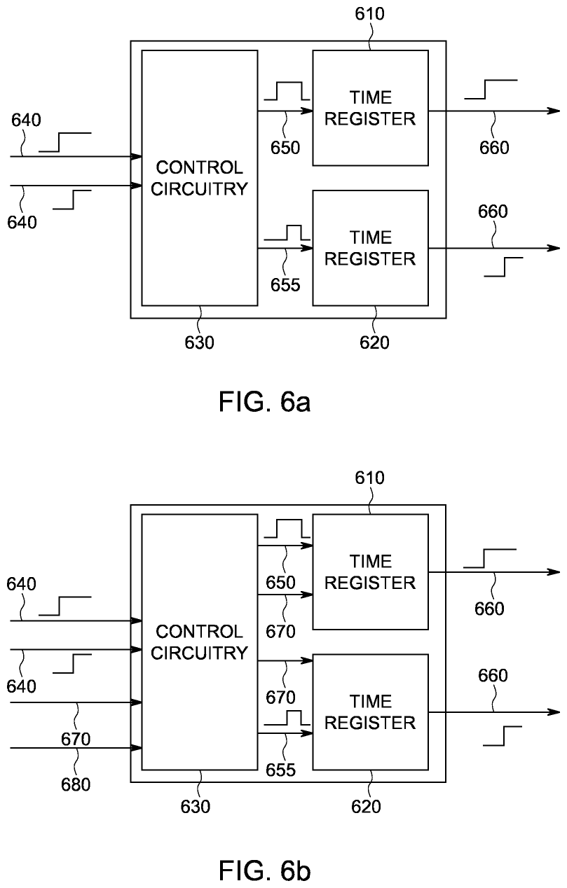

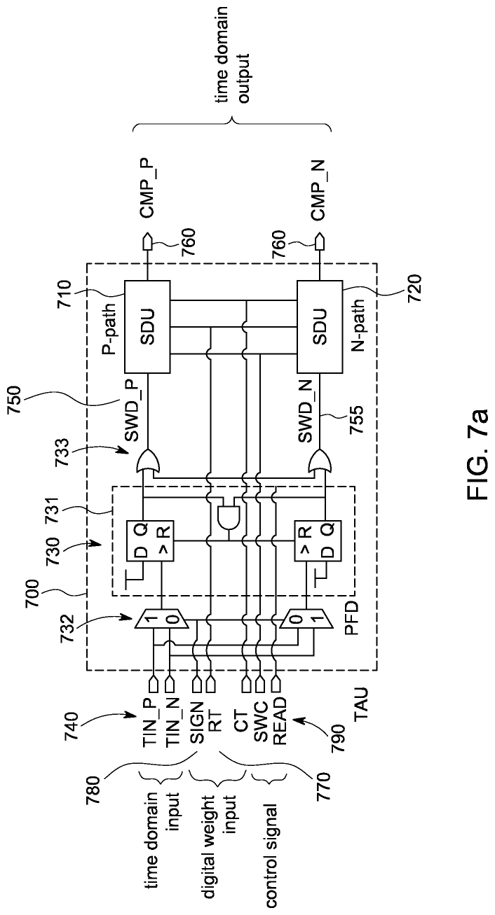

The circuit arrangement 400 shown in FIGS. 4a and 4b is suitable for use as a time-register (or SDU) in a TAU. Therefore, the circuit arrangement 400 may be denoted a time-register circuit arrangement or a SDU circuit arrangement. Its application in a TAU is shown with respect to FIGS. 6a to 7b.

As shown in FIG. 4a, the circuit arrangement 400 comprises a capacitive circuit element 410, which is used as basis of the time-mode operation being performed by the circuit arrangement. For example, the capacitive circuit element may be implemented using one or more capacitors, such as a capacitor bank. For example, the capacitive circuit element may be implemented as part of a semiconductor die, i.e., without requiring external capacitors.

In an initial state, the capacitor is charged, e.g., by a voltage source of the circuit arrangement, as shown in FIG. 5a (which is a simplified model), or a supply voltage of the circuit arrangement. In other words, in an initial state of the circuit arrangement, the capacitive circuit element may be charged to an initial voltage (V_{INIT}). During operation of the circuit arrangement, the charges stored in the capacitive circuit arrangement are discarded (i.e., discharged, removed from the capacitive circuit element), which reduces the voltage between the terminals of the capacitive circuit element.

The circuit arrangement is configured to discard charges from the capacitive circuit element 410 based on a width of one or more signal pulses of an input signal 440 being provided to the circuit arrangement. In other words, depending on the width of signal pulses of the input signal, the charges are removed from the capacitive circuit element, thus reducing the voltage between the terminals of the capacitive circuit element. Accordingly, the input signal may be a pulse-width-based input signal, with the information contained in the input signal being represented by the width of the pulse(s). For example, the charges may be removed by arranging a resistive circuit element 420 (as shown in FIG. 4b) in parallel to the capacitive circuit element 410 and discharging the capacitive circuit element 410 via the resistive circuit element 420. In other words, the circuit arrangement may comprise the resistive circuit element 420, which may comprise a resistor or resistor bank (i.e., a plurality of resistors being selectively connected in line via a control circuitry). To make the discharge conditional on the input signal, the resistive circuit element 420 may be coupled with a switch (e.g., as shown in FIG. 5a), which may be arranged in line with the resistive circuit element 410. The switch may be configured to connect the resistive circuit element to ground depending on the input signal (e.g., such that the connection is established, and thus the capacitive circuit element is discharged, based on the pulse(s) included in the input signal).

Alternatively, the capacitive circuit element may be discharged using an active circuit element, such as a current source that is configured to remove charges from the capacitive circuit element. Again, the active circuit element (e.g., current source) may be configured to discharge the capacitive circuit element depending on the input signal (e.g., such that the capacitive circuit element is discharged based on the pulse(s) included in the input signal).

Compared to the time-register shown in FIG. 3a, the circuit arrangement/time-register of FIGS. 4a to 5a is capable of varying the rate at which the charges are discarded, dependent on the at least one control signal 450. This can be achieved via different mechanisms.

For example, the capacitive circuit element 410 may be a tunable capacitive circuit element. For example, the tunable capacitive circuit element may be configured to vary its capacitance based on the at least one control signal. For example, the tunable capacitive circuit element may be implemented using a capacitor bank, with the capacitors of the capacitor bank being used being dependent on the at least one control signal. By varying the capacitance of the capacitive circuit element, the rate at which the charges are discarded can be varied. The circuit arrangement may be configured to vary the rate at which the charges are discarded by controlling (e.g., adjusting or varying) the capacitance of the tunable capacitive circuit element based on the at least one control signal.

Alternatively, or additionally, the electrical resistance of the resistive circuit element may be varied. In other words, the resistive circuit element may be a tunable resistive circuit element. For example, the tunable resistive circuit element may be a varistor, or may be implemented using the resistor bank, with the resistors of the resistor bank being used being dependent on the at least one control signal. By varying the electrical resistance of the resistive circuit element, the rate at which the charges are discarded can be varied. Accordingly, the circuit arrangement may be configured to vary the rate at which the charges are discarded by controlling the electrical resistance of the tunable resistive element based on the at least one control signal.

If an active circuit element, such as a power source, is used to discharge the capacitive circuit element, the rate at which the charges are discarded can be varied by controlling the active circuit element (e.g., the power source), based on the at least one input signal. Accordingly, the circuit arrangement may be configured to vary the rate at which the charges are discarded by controlling the rate of discharge being provided by the active circuit element based on the at least one control signal.

The output of the circuit arrangement, and in particular the timing of the output flank, is dependent on the charges remaining the capacitive circuit element after the pulse(s) included in the input signal have caused the charges to be discarded. In particular, the output signal flank has a delay relative to a readout signal flank being provided to the circuit arrangement, with the delay being based on the charges stored in the capacitive circuit element at the time the readout signal flank is provided to the circuit arrangement. The circuit arrangement 400 may comprise, as further shown in FIG. 4b, an output circuit element 430, configured to provide the output signal flank having the delay relative to the readout signal.

The proposed circuit arrangement is a circuit arrangement that is suitable for use in a time-mode circuit. Accordingly, the output of the circuit arrangement is provided in terms of a delay between two signal flanks, i.e., between the readout signal flank and the output signal flank. Therefore, the charges remaining in the capacitive circuit element may be determined by the circuit arrangement, e.g., by the output circuit element 430, and the amount of charges may be represented by the delay of the output signal flank relative to the readout signal flank.

To determine the amount of charges remaining in the capacitive circuit element at the time the readout signal flank is provided, the time that is required for further discharging the capacitive circuit element (until a (pre-defined) voltage threshold Vₜₕ for the voltage between the two terminals of the capacitive circuit element) may be used. This is possible, as the time required for discharging the capacitive circuit element (to the voltage threshold) is related to the amount of charges remaining in the capacitive circuit element at the time the readout signal flank is provided. For example, the circuit arrangement may be configured to discard the charges remaining in the capacitive circuit element (until the pre-defined voltage threshold is reached) in response to the readout signal flank. For example, both the input signal and the readout signal may be combined in an OR gate (or similar, depending on whether the switch is closed with a high or low signal state), or the readout signal may be part of the input signal, and be used to drive the switch that is in line with the resistive circuit element or to drive the active circuit element (e.g., the power source). Once the voltage threshold is reached, the output signal flank may be generated and provided as part of the output signal. To trigger the output signal flank once the voltage between the terminals of the capacitive circuit element is reached, a comparator may be used, which may be configured to compare the voltage between the terminals of the capacitive circuit element to the voltage threshold, and to trigger the output signal flank once the voltage threshold is reached. Accordingly, the output circuit element may be a comparator circuit, configured to trigger the output signal flank when a voltage representing the charges remaining in the capacitive circuit element reaches the voltage threshold. In effect, the delay of the output signal flank relative to the readout signal flank represents the charges remaining in the capacitive circuit element at the time the readout signal flank is provided, with the amount of charges being dependent on the initial voltage and the amount of charges being discarded in response to the pulse(s) included in the input signal.

Once the remaining charges are discarded, the readout signal may be set to a state that opens the switch that is line with the resistive circuit element or deactivates the active circuit element, and the capacitive circuit element may be re-charged, e.g., by connecting the capacitive circuit element to the supply voltage or to a voltage source. This resets the circuit arrangement, preparing it for a subsequent use.

The circuit arrangement outlined in connection with FIGS. 4a and 4b has been described in broad terms. The circuit arrangement may comprise several additional and ancillary components, such as circuitry for calibrating the capacitive circuit element and/or the (optional) resistive circuit element, and control circuitry for driving the switch(es) and for re-charging the capacitive circuit element.

In general, the circuit arrangement may be implemented using various technologies and techniques. In some examples, as has been outlined before, the circuit arrangement may be used in an ADPLL. To enable an implementation of the ADPLL that is independent of external components, such as external capacitors, the proposed circuit arrangement may be implemented entirely in a semiconductor die, e.g., by using a capacitive circuit element that uses the layers of a layer stack of the semiconductor die as capacitor plates, and/or by using meanders to implement the resistive circuit element. In other words, the circuit arrangement, e.g., including the capacitive circuit element, may be implemented in a semiconductor die.

More details and aspects of the circuit arrangement are mentioned in connection with the proposed concept or one or more examples described above or below (e.g. FIG. 1 to 3b, 5a to 11). The circuit arrangement may comprise one or more additional optional features corresponding to one or more aspects of the proposed concept or one or more examples described above or below.

In FIG. 5a, a further example of the (time-register) circuit arrangement is shown, which highlights the difference of the proposed circuit arrangement to the time-register shown in FIG. 3a.

FIG. 5a shows a schematic diagram of an example of a circuit arrangement 500, which is denoted successive discharge unit (SDU). For example, the SDU 500 of FIG. 5a may be implemented similar to the circuit arrangement of FIGS. 4a and/or 4b. The circuit arrangement 500 is configured to discard charges from a tunable capacitive circuit element C 510 of the circuit arrangement via a resistive circuit element R 520 based on a width of one or more signal pulses of an input signal SWD 540 being provided to the circuit arrangement.

The rate at which the charges are discarded is dependent on at least one control signal RT, CT 550 being provided to the circuit arrangement. In FIG. 5a, the circuit arrangement is configured to vary the rate at which the charges are discarded by controlling a capacitance of the tunable capacitive circuit element based on a first component CT of the at least one control signal and/or by controlling an electrical resistance of the tunable resistive element based on a second component RT of the at least one control signal.

The circuit arrangement 500 is configured to provide an output signal flank 565 (shown in FIG. 5b) having a delay relative to a readout signal flank 545 (shown in FIG. 5b as part of the input signal SWD) being provided to the circuit arrangement, with the delay being based on the charges stored in the capacitive circuit element at the time the readout signal flank is provided to the circuit arrangement. For example, as shown in FIG. 5a, the circuit arrangement may be configured to discard the charges remaining in the capacitive circuit element in response to the readout signal flank. A comparator circuit may be configured provide the output signal flank, with the comparator circuit being configured to trigger the output signal flank when a voltage V_{c} representing the charges remaining in the capacitive circuit element reaches a voltage threshold Vₜₕ.

An example of a corresponding waveform is shown in FIG. 5b. As can be seen in FIG. 5b, different RC-values τ₁ . . . τₙ may be used for successive discharges of a cycle. A separate RC-value τₒᵤₜ may be used for discharging the charges remaining from Vₙ until the threshold voltage Vₜₕ. The delay time between the readout signal flank 545 and the output signal flank 565 is denoted Δtₒᵤₜ in FIG. 5b.

More details and aspects of the SDU are mentioned in connection with the proposed concept or one or more examples described above or below (e.g., FIG. 1 to 4b, 6 to 11). The SDU may comprise one or more additional optional features corresponding to one or more aspects of the proposed concept or one or more examples described above or below.

The (time-register) circuit arrangement or SDU outlined in connection with FIGS. 4a to 5b, which adds weights to the time register, paves the way for the implementation of the TAU circuit arrangement introduced in connection with FIGS. 6a to 7b. However, the (time-register) circuit arrangement/SDU differs from the TAU circuit arrangement in some respects. As will be shown in the following, the input of a TAU is a time-mode signal, which is defined as the time difference between certain signal flanks (i.e., signal edges). However, the (time-register) circuit arrangement/SDU is configured to process the width of pulses. Additionally, according to Equation (1), the weights wᵢ can be arbitrary real numbers. However, Equation (3) suggests that the (time-register) circuit arrangement/SDU uses (only) negative weights. Moreover, an undesired constant term,

$${τ}_{out} ln ( \frac{{V}_{init}}{{V}_{th}} ) ,$$

may exist in the transfer function of the (time-register) circuit arrangement/SDU, and thus its output. This may introduce some sensitivity to PVT variations to the output of the (time-register) circuit arrangement/SDU.

For example, to address these issues, the proposed TAU circuit arrangement comprises a combination of two parallel SDUs with some auxiliary circuits, e.g., a control circuitry. The schematic and waveform of various examples of the proposed TAU circuit arrangement are shown in FIGS. 6a to 7a and FIG. 7b, respectively.

FIGS. 6a and 6b shows block diagrams of example of a TAU circuit arrangement 600. The TAU circuit arrangement 600 comprises at least a first and a second (time-register) circuit arrangement/SDU 610; 620, e.g., the (time-register) circuit arrangement/SDU introduced in connection with FIGS. 4a to 5b. The TAU circuit arrangement 600 comprises control circuitry 630. The control circuitry is configured to convert a time-mode input signal 640 comprising at least a first pair of input signal flanks to a first and a second input signal 650; 655. The first and second input signal each comprise at least a first signal pulse having a pulse width being based on a delay between the flanks of the first pair of input signal flanks. The control circuitry is configured to provide the first and second input signal to the first and second circuit arrangement. The control circuitry is configured to provide a time-mode output signal 660 comprising a pair of output signal flanks based on respective output signals of the first and second circuit arrangements.

In FIGS. 6a to 6b, a schematic example of a TAU circuit arrangement is shown. A more detailed implementation is shown in connection with FIG. 7a. However, many of the concepts of the examples shown in connection with FIGS. 6a and 6b apply to the example shown in FIG. 7a, and vice versa.

As is apparent from FIGS. 6a and 6b, the TAU is based on two groups of components—the first and second (time-register) circuit arrangement/SDU 610; 620, and the control circuitry 630. In general, the control circuitry is configured to generate the input signals being provided to the (time-register) circuit arrangements/SDUs 610; 620, by converting the time-mode input signal to the pulse-width-based input signals of the (time-register) circuit arrangements/SDUs 610; 620, with the input signals of the (time-register) circuit arrangements/SDUs 610; 620 carrying their respective information in terms of the width of the pulses carried on the signals. In other words, the input signals of the (time-register) circuit arrangements/SDUs 610; 620 may be pulse-width-based input signals.

The control circuitry is configured to convert the time-mode input signal 640 comprising at least a first pair of input signal flanks to a first and a second input signal 650; 655, which each comprise at least a first signal pulse having a pulse width being based on a delay between the flanks of the first pair of input signal flanks. In other words, the control circuitry may be configured to convert a time-mode input signal, which carries information using a delay between successive signal flanks (with the successive signal flanks being carried by different signal components in the examples given in the present disclosure), to signals that carry information using a width of the signal pulse(s) included in the signal. Moreover, to drive the first and second (time-register) circuit arrangement/SDU 610; 620 in a manner that enables a time-mode computation, the control circuitry may be configured to translate the information carried by the time-mode input signal to generate the first and second input signals carrying equivalent information in terms of the width of the signal pulses included in the input signals. For example, as shown in FIG. 7b, the time-mode input signal may comprise two signal components, with each signal component carrying one input signal flank of each pair of input signal flanks.

This may be done by applying the delay between the flanks of the first pair of input signal flanks to a difference in pulse width between the two input signals. For example, the first signal pulse of the first input signal may have a pulse width being different from a pulse width of the first signal pulse of the second input signal if the delay between the signal flanks of the first pair of input signal flanks is greater than zero. In other words, as long as the flanks of the first pair of input signal flanks do arrive at different times (i.e., one before the other), the width of the first pulses of the first and second input signal may be different. Moreover, the difference in pulse width between the first pulses of the first and second input signal may be (linearly) dependent on the delay between the flanks of the first pair of input signal flanks. For example, as shown in FIG. 7b, the difference (Δt₁ in FIG. 7b) between the pulse widths of the first pulses may be equal to the delay between the flanks of the first pair of input signal flanks. The case of the delay between the flanks of the pair of input signal flanks being zero may occur in a PLL, if there happens to be no instantaneous phase error in the control loop, i.e., the clock edges of the oscillator and the reference clock are aligned. In that case the PLL should also not control the loop in any direction, i.e., the time-mode output signal may be zero.

To select between which of the first pulses is to be wider, a sign setting signal 680 (shown in FIG. 6b) may be used. For example, the control circuitry may be configured to switch between generating signal pulses having a wider pulse width for the first input signal and generating signal pulses having a wider pulse width for the second input signal based on a sign setting signal 680 being provided to the TAU circuit arrangement. For example, the sign setting signal may be used to indicate whether a summand being processed by the TAU circuit arrangement is positive or negative. The processing of positive or negative summands may be implemented by switching between providing wider signal pulses on the first or on the second input signal.

There are various types of circuits that can be used to convert the time-mode input signal to the first and second input signals. For example, asynchronous flip-flops may be used for this purpose. In FIG. 7a, a phase frequency detector circuitry 731 is shown, which is implemented using two D-flipflops and additional circuitry, and which is used to convert the time-mode input signal to the first and second input signal. Accordingly, the control circuitry may comprise a phase frequency detector circuitry for converting the time-mode input signal to the first and second input signal, thereby converting signal flanks to pulse widths. Once the first and second input signals are generated by the control circuitry, they are provided as input signals to the first and second (time-register) circuit arrangement/SDU 610; 620.

In the most basic configuration, a single pair of input signal flanks, and thus also a single pulse being derived from the pair of input signal flanks and provided as part of the first and second input signal suffices to drive the TAU circuit arrangement, e.g., for using the TAU circuit arrangement in a time-scaling operation. However, to use the TAU circuit arrangement for a summation of two or more summands, at least one further pair of input signal flanks may be included in the time-mode input signal and at least one corresponding further signal pulse may be included in the first and second input signals. In other words, the control circuitry may be configured to provide, if the time-mode input signal further comprises at least one further pair of input signal flanks, each of the first and second input signals with at least one further signal pulse having a pulse width being based on a delay between the signal flanks of the at least one further pair of input signal flanks. For example, each of the at least one further pair of input signal flanks may be converted to corresponding pulses on the first and second input signals similar to the conversion of the first pair of input signal pulses to the first pulse. In other words, the control circuitry may be configured to convert the at least one further pair of input signal flanks to corresponding at least one further signal pulses on each of the first and second input signal.

In this basic configuration of the TAU circuit arrangement, the features for controlling the weight of individual summands are not yet used. Even without consideration of different weights for different summands, once at least two pairs of input signal flanks are used, a summation of the summands being represented by the at least two pairs of input signal flanks may be performed by the TAU circuit arrangement. In other words, the TAU circuit arrangement may be configured to perform a time-mode summation of the delay between the signal flanks of the first pair of input signal flanks and the delay between the signal flanks of the at least one further pair of input signal flanks. The result may be provided at the output of the TAU circuit arrangement. In other words, the delay between the pair of output signal flanks may represent the result of the time-mode summation. For example, the control circuitry may be configured to provide the respective output signals comprising the respective output signal flanks as time-mode output signal. Accordingly, as shown in FIG. 7b, the output signal may comprise two signal components, each carrying one of the output signal flanks. As will be illustrated in connection with FIG. 7b, the output signal flanks of the time-mode output signal represent the result of the computation (e.g., of the time-mode summation) based on the delay between the output signal flanks being carried by the respective output signals of the first and second (time-register) circuit arrangement/SDU 610; 620, with the reference to the readout signal flank used being eliminated if a common readout signal flank is used for both (time-register) circuit arrangements/SDUs 610; 620. Moreover, the (undesired) constant term

$${τ}_{out} ln ( \frac{{V}_{init}}{{V}_{th}} )$$

can be eliminated, if τₒᵤₜ, Vᵢₙᵢₜ and Vₜₕ are the same (or equivalent, in case calibration is applied) for both (time-register) circuit arrangements/SDUs 610; 620.

As outline above, in various examples, the time-mode summation may be extended by enabling a weighted time-mode summation. Such weighting can be applied using the at least one control signal introduced in connection with FIGS. 4a to 5b. For example, the control circuitry may be configured to provide at least one control signal 670 to the first and second circuit arrangement. For example, the at least one control signal may be configured to control the rate at which charges are being discarded from a capacitive circuit element of the respective circuit arrangements. Examples on an implementation of the at least one control signal are introduced in connection with FIGS. 4a to 5b. For example, the control signal may be used to control at least one of a capacitance of the respective capacitive circuit element, an electrical resistance of a respective resistive circuit element of the (time-register) circuit arrangements/SDUs, and an active circuit element, such as a power source, to control the rate at which the charges are discarded from the respective capacitive circuit elements. In general, the same control signals may be provided to both (time-register) circuit arrangements/SDUs, so the weighting factor is uniformly applied to both branches. Alternatively, different control signals may be provided, e.g., to account for a calibration of the respective (time-register) circuit arrangements/SDUs. In effect, the control circuitry may be configured to provide the at least one control signal such, that the rate at which charges are being discarded from the capacitive circuit elements is the same for the first and second circuit arrangement. Alternatively, the at least one control signal may be provided such, that the rate at which charges are being discarded from the capacitive circuit element is different for the first and second circuit arrangement.

As can be seen in FIGS. 6a to 7a, the control circuitry may be configured to obtain the at least one control signal from an external entity (e.g., from an external entity integrating the TAU circuit arrangement), and to provide (e.g., route) the at least one control signal obtained from the external entity to the first and second (time-register) circuit arrangement/SDU. In some cases, the control circuitry may be configured to process a control signal that is provided by an external entity, and to generate the at least one control signal for the first and second (time-register) circuit arrangement/SDU based on the control signal that is provided by the external entity, e.g., to adjust the control signal with respect to a calibration of the first and second (time-register) circuit arrangement/SDU. In some cases, the control circuitry may be configured to generate the at least one control signal without external input. Moreover, as shown in FIG. 7a, the control circuitry may be configured to provide the readout signal to the first and second (time-register) circuit arrangement/SDU, e.g., as part of the respective input signals. For example, the control circuitry may be configured to insert the readout signal flank for the first and second (time-register) circuit arrangement/SDU into the first and second input signal, e.g., via an OR gate. Similarly, the readout signal may be obtained from the external entity or generated by the control circuitry of the TAU circuit arrangement.

When a weighted time-mode summation is to be performed, the at least one control signal may be updated for the different summands, such that the different summands receive different weights. For example, the control signal provided during the first and at least one further time intervals may act as weighting factor, influencing the amount of charges being discarded in response to the first and at least one further signal pulses included in the first and second input signal. To adjust the weighting factor, the at least one control signal may be updated between the pulses being provided as summands to the (time-register) circuit arrangement/SDUs.

Accordingly, the control circuitry may be configured to provide the control signal during at least a first time interval (for the first summand), a final time interval (for the readout), and, optionally, at least one further time interval (for at least one further summand). The first time interval may encompass the first signal pulses being provided as part of the first and second input signal (representing the first summand). The at least one further time interval may encompass the at least one further signal pulse being provided as part of each of the first and second input signal (representing the at least one further summand). The final time interval may encompass a time between the readout signal flank and the provision of the pair of output signal flanks of the output signal (and control a scaling of the result of the summation). In other words, each of the summands (and the readout) may be accompanied by a corresponding setting being set by the at least one control signal. For example, the at least one control signal may be updated (e.g., by the external entity and/or by the control circuitry) for each of the first time interval, the at least one further time interval and the final time interval. Accordingly, the control circuitry may be configured to update the at least one control signal for each of the first time interval, the at least one further time interval and the final time interval.

By updating the at least one control signal for each time interval, different weights may be used to perform a weighted time-mode summation. The TAU circuit arrangement may be configured to perform a time-mode weighted summation of the delay between the signal flanks of the first pair of input signal flanks and the delay between the signal flanks of the at least one further pair of input signal flanks, weighted by the respective weighting factor(s) (which may be updated for each summand), with the delay between the pair of output signal flanks representing the result of the time-mode weighted summation. If weights are not required during the time-mode summation, the at least one control signal may remain constant over the time intervals.

To further increase the capabilities of the TAU circuit arrangement, the TAU circuit arrangement may be configured to perform a time-mode summation with positive and/or negative summands. In other words, the first summand and the at least one further summands may each be positive or negative. To distinguish between positive and negative summands, the aforementioned sign setting signal 680 may be used, which may be used, by the control circuitry, in the conversion of the time-mode input signal to the first and second input signals. For example, the TAU circuit arrangement may be configured to perform a (weighted) time-mode summation of the delay between the flanks of the first pair of input signal flanks (representing the first summand) and the delay between flanks of at least one further pair of input signal flanks (representing the at least one further summand). The sign setting signal may be used to select between a summand being positive or negative. Again, the pair of output signal flanks may represent the result of the time-mode summation.

As outlined above, the TAU circuit arrangement may be used to scale time-mode signals, e.g., by reducing or extending the delay between the two signal flanks of the time-mode signal according to a scaling factor. This is done via the at least one control signal being applied during the final time interval—the higher the rate at which the charges are discarded is being set, the shorter is the delay between the output signal flanks (which may reduce the delay between the output signal flanks), and the lower the rate at which the charges are discarded is being set, the longer is the delay between the output signal flanks (which may extend the delay) between the output signal flanks. In other words, the control signal provided during the final time interval acts as scaling factor, influencing a time delay between the pair of output signal flanks. In effect, the TAU circuit arrangement may be configured to perform a (weighted) time-mode summation of the delay between the signal flanks of the first pair of input signal flanks and the delay between the signal flanks of the at least one further pair of input signal flanks, with the delay between the pair of output signal flanks representing the result of the time-mode summation, multiplied by the scaling factor.

For example, the control circuitry may be configured to update the control signal for the final time interval such, that the rate, at which charges are being discarded from the capacitive circuit element of the respective circuit arrangements, is set according to a scaling control signal. As outlined above, the scaling factor may be set to reduce or extend the delay between the output signal flanks, thus applying a scaling factor of <1 or >1. Additionally, the scaling factor may be set to 1 if no scaling is required. Accordingly, the rate at which charges are being discarded from the capacitive circuit element of the respective circuit elements during the final time interval may be settable to be smaller than (for a scaling factor >1), equal to (no scaling), and greater than (for a scaling factor <1) the rate at which charges are being discarded from the capacitive circuit element of the respective circuit elements during the first time interval via the scaling control signal.

Similar to the (time-register) circuit arrangement/SDU of FIGS. 4a to 5b, the TAU circuit arrangement may be implemented using different technologies, e.g., using discrete components. In some examples, as outlined in connection with FIGS. 4a and 4b, the proposed concept may be used in an ADPLL or similar circuitry, where the aim is to implement the entire circuitry on-die. Accordingly, the TAU circuit arrangement may be (entirely) implemented in a semiconductor die, e.g., without using external capacitive circuit elements.

More details and aspects of the TAU circuit arrangement are mentioned in connection with the proposed concept or one or more examples described above or below (e.g., FIG. 1a to 5b, 7a to 11). The TAU circuit arrangement may comprise one or more additional optional features corresponding to one or more aspects of the proposed concept or one or more examples described above or below.

In FIGS. 6a to 6b, a high-level example of a TAU circuit arrangement has been introduced. In the following, a more detailed example is given, which may be used to implement the TAU circuit arrangement shown in connection with FIGS. 6a to 6b. In the context of the present disclosure, the terms TAU and TAU circuit arrangement may be used interchangeably.

FIG. 7a shows a schematic diagram of an example of a TAU circuit arrangement 700. The TAU circuit arrangement 700 comprises at least a first and a second (time-register) circuit arrangement/SDU 710; 720, e.g., as introduced in connection with FIGS. 4a to 5b. In FIG. 7a, the first SDU 710 is denoted P-path SDU, and the second SDU 720 is denoted N-path SDU, as the time-mode output signal composed of CMP_P and CMP_P may be considered to form a differential signal, i.e., two signal components carrying differential information. In particular, the output of the TAU circuit arrangement may be defined as the delay between the output signal flanks carried by the two components, CMP_P and CMP_N of the time-mode output signal.

The TAU circuit arrangement 700 further comprises control circuitry 730. The control circuitry 730 is configured to convert a time-mode input signal 740 TIN_P, TIN_N comprising at least a first pair of input signal flanks to a first and a second input signal SWD_P, SWD_N 750; 755, with the first and second input signal each comprising at least a first signal pulse having a pulse width being based on a delay between the flanks of the first pair of input signal flanks. As will become evident in connection with FIG. 7b, the control circuitry is configured to provide, if the time-mode input signal further comprises at least one further pair of input signal flanks, each of the first and second input signals with at least one further signal pulse having a pulse width being based on a delay between the signal flanks of the at least one further pair of input signal flanks. In FIG. 7b, the duration of the different pulses carried by the input signals is denoted with Δtᵢ for the first pulse and Δtₙ for a further pulse. In FIG. 7a, the control circuitry comprises a phase frequency detector circuitry 731 for converting the time-mode input signal to the first and second input signal, thereby converting signal flanks to pulse widths. In FIG. 7a, the D-port of the are constantly high (i.e., connected to supply voltage). If the signal edge arrives at the input, the flipflop output is set to high. After the second signal edge arrives, the second flipflop output is set high as well. If both flipflops are high, the reset port is triggered (via the AND-gate included in the frequency detector circuitry, and the flipflop outputs are set low again.

The control circuitry 730, e.g., the phase frequency detector circuitry 731, combined with two OR gates 733 for including the readout signal flanks of the READ signal, is configured to provide the first and second input signal to the first and second circuit arrangement. In addition, a sign setting signal SIGN 780 influences the first and second input signal. The control circuitry, by using multiplexers 732 to switch the components TIN_P and TIN_N of the time-mode input signal, is configured to switch between generating signal pulses having a wider pulse width for the first input signal and generating signal pulses having a wider pulse width for the second input signal based on the sign setting signal SIGN 780 being provided to the TAU circuit arrangement. The sign setting signal may depend on whether the one or the other signal edge is leading. In FIG. 7b, an example is shown what effect the sign setting signal can have on the signal chain. When being used in an ADPLL, additional control circuits may take care that the sign setting signal is properly set, depending on the order of the signal edges. The control circuitry 730 of FIG. 7a is further configured to provide at least one control signal CT RT 770 to the first and second circuit arrangement, with the at least one control signal being configured to control the rate at which charges are being discarded from a capacitive circuit element of the respective circuit arrangements.

The control circuitry 730 is further configured to provide a time-mode output signal CMD_P CMD_N 760 comprising a pair of output signal flanks based on respective output signals of the first and second circuit arrangements. For example, the TAU circuit arrangement of FIG. 7a may be implemented similar to the TAU circuit arrangement of FIGS. 6a and/or 6b.

FIG. 7b shows a diagram of an example of a waveform of a TAU, e.g., the TAU circuit arrangement shown in FIG. 7a. FIG. 7b shows the time-mode input signal TIN_P, TIN_N 740, the sign setting signal SIGN 780, the first and second input signal SWD_P SWD_N 750; 755, the at least one control signal RT CT 770, the resulting RC-constant τ, the control signal SWC being used to control the switch for re-charging the capacitive circuit elements, the readout signal READ 790, and the time-mode output signal having two components CMP_P CMP_N 760. FIG. 7b further shows the delays Δt₁, Δtₙ between the input signal flanks, which influence the pulse widths of the signal pulses on the input signals SWD_P, SWD_N 750; 755, and the delay Δtₒᵤₜ between the output signal flanks. The “D” shown in FIG. 7b corresponds to the propagation delay of the reset signal from D-port to the reset port (incl. reset port latency) of the flipflops being used.

For this TAU implementation, the time domain input is the time difference between the rising edges of TIN_P and TIN_N. The MUXs 732, which are controlled by the sign setting signal SIGN 780, can inverse the input time difference by swapping TIN_P and TIN_N, thus introducing sign to the weights. A PFD (phase frequency detector) 731, which is commonly used in PLLs (Phase-Locked Loops), converts the time difference between the rising edges of the time-mode input signal to a pulse-width, which is the form of time signal required by the SDUs. The same as in the (time-register) circuit arrangement/SDU shown in connection with FIGS. 4a to 5b, the SWC signal controls the pre-charge for initialization, while the control signals RT and CT 770 control the amplitude of weight for each input time difference by varying r while discharging. In general, each of the paths may be discharged with individual discharge pulses and/or τ, i.e., each SDU may have its own SWC, RT and CT signal, or common signals may be used. After the SDUs have processed all the desired input time differences, a rising edge of READ (i.e., the readout signal flank) can trigger their last discharge (i.e., read-out), and the time-mode signal output may be evaluated in the form of a time difference between CMP_P and CMP_N falling edges (i.e., the output signal flanks), whose value can be formulated as

$$Δ {t}_{out} = {\sum }_{i = 1}^{n} {sgn}_{i} \frac{{τ}_{out}}{{τ}_{i}} Δ {t}_{i} , \qquad ( 4 )$$

where sgnᵢ=1 when SIGN is high and sgnᵢ=−1 when SIGN is low. And by comparing Equation (1) and Equation (4), it can be concluded that the output of the implemented TAU is the same as that of the defined TAU in equation (1) if

$${w}_{i} = {sgn}_{i} \frac{{τ}_{o u t}}{{τ}_{i}} .$$

In some examples, the proposed system can also work as a time amplifier if τₒᵤₜ>τᵢ, or more generally, as a time scaler if τₒᵤₜ≈τᵢ. This can be used, for example, to relax the requirements for the following TDC. It is also worth mentioning that, even though time amplification can also be provided by other circuits, the proposed TAU may provide a low-complexity possibility to add a TA factor to the weighted sum, since it only requires some additional control circuits to adjust the time constant of the final read-out discharge period.

It is evident, that the voltage-dependent constant term of Equation (3) is gone in Equation (4), improving the PVT robustness. Furthermore, due to the differential structure, any distortions caused by the circuit will cancel at the output if both paths are identical.

FIGS. 7a and 7b show an example of a (conceptual) implementation of the proposed TAU. However, the implementation of the SDU (e.g., as shown in FIGS. 4a to 5b) is not limited to the combination of tunable resistors and capacitors. Any combination of devices that can change the slope of a discharge/charge curve can be used as SDU. Moreover, the auxiliary circuits for TAU are not limited to the example given in FIG. 7a, which is the combination of MUXs, PFD (Phase Frequency Detector) and OR gates. Any combination of circuits that can swap and combine input edges and convert them to pulses can also be used.

More details and aspects of the TAU circuit arrangement are mentioned in connection with the proposed concept or one or more examples described above or below (e.g., FIG. 1a to 6b, 8 to 11). The TAU circuit arrangement may comprise one or more additional optional features corresponding to one or more aspects of the proposed concept or one or more examples described above or below.

As outlined above, a major application of the proposed TAU circuit arrangement is as part of an All-Digital Phase-Locked Loop (ADPLL). For example, within an ADPLL, the time error information can be processed directly in time domain before digitizing it. The proposed TAU circuit arrangement may be to calculate the weighted sum of input time in time domain. By utilizing a TAU circuit arrangement, the ADPLL can combine the DTC and time amplifier, lower the requirement on DTC gain calibration and achieve variable time amplification gain.

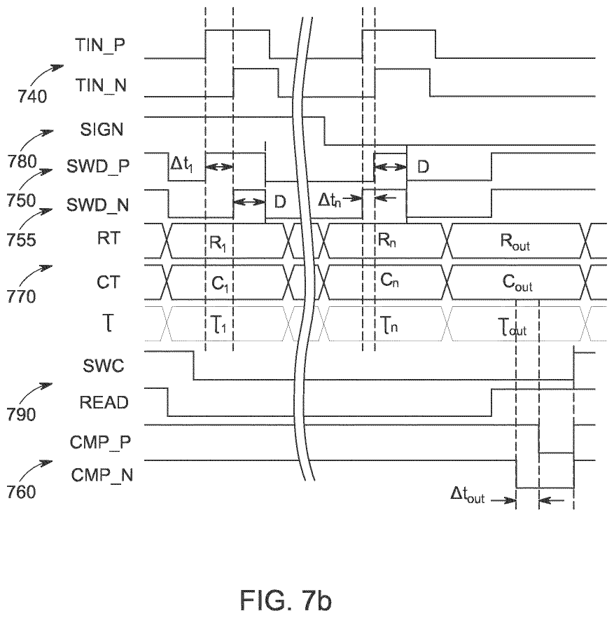

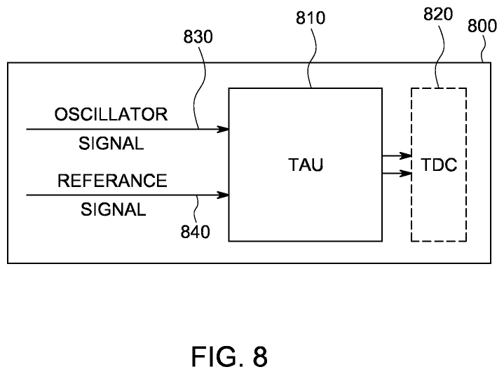

FIGS. 8 and 9 show schematic diagrams of examples ADPLLs with a TAU circuit arrangement. FIG. 8 shows a schematic diagram of an example of an ADPLL circuit arrangement comprising a TAU circuit arrangement, e.g., the TAU circuit arrangement introduced in connection with at least one of FIGS. 6a to 7a. For example, as shown in FIG. 8, the TAU circuit arrangement 810 may be used to capture an offset (i.e., delay) between an oscillator signal 830 and a signal flank of a reference signal 840 of the ADPLL circuit arrangement. Accordingly, the time-mode output signal of the TAU circuit arrangement may represent the offset between the oscillator signal and the signal flank of the reference signal. As further shown in FIG. 8, the time-mode output signal of the TAU circuit arrangement may be provided to a Time-to-Digital Converter (TDC) 820, which may be configured to quantize the time-mode output signal, for use in calibration of the TAU or for use in a Digital Loop Filter.

In many cases, TDCs have certain capabilities in terms of resolution, for example, with a higher resolution resulting in more complexity and power consumption. By using the time-scaling function (e.g., time amplification function of the TAU circuit arrangement), the TAU circuit arrangement can tailor its time-mode output signal to the capabilities of the TDC. Accordingly, the scaling factor may be used to scale the delay between the pair of output signal flanks for the Time to Digital Converter 820 of the ADPLL circuit arrangement. For example, the scaling factor may be >1 or =1 or <1. Each setting has its benefit, depending on the application. In case of a PLL, if the scaling factor is >1, the TDC resolution can be improved (or the required resolution of the TDC can be reduced) in case the phase error of the PLL is already small, i.e., the PLL is frequency locked and operates in (quasi) steady-state mode. If the PLL, for example, slightly loses its frequency lock, one can speed-up the control loop, by setting the time amplification to <1. This allows the TDC to digitize larger phase errors and gives a chance to “catch-up” and in best case achieving a locked PLL operation again. This may cause the TDC to have a coarser phase error at its output, i.e., larger quantization error. However, in case the frequency lock is lost, quantization error is only a minor source of error. In effect, the time-amplification or time-scaling may be used to either reduce the requirement of the TDC resolution (and in doing so reducing the power consumption) or, equivalently, to improve the TDC resolution (and in doing so reducing the quantization noise in the system). In this case, noise performance and power consumption are directly related and can be trade against each other.

The required range which the TDC has to cover can also be reduced, since the TAU circuit arrangement can already perform major portions of the task of a digital-to-time converter (DTC). A DTC knows the fractional relation between the tuned oscillator period and the reference clock period. If this is a fractional ratio, there may be a deterministic offset between the oscillator edge and the reference edge for each reference period. The DTC or TAU may be aware of this ratio and consider only the remaining phase error between the two signals, i.e., the actual phase error, which the PLL may control. In doing so, the TDC may cover a lower fraction of the oscillator period, thus reducing the requirement of the TDC dynamic range.

As outlined in connection with FIGS. 4a to 4b and 6a to 6b, the ADPLL circuit arrangement may be entirely implemented in a semiconductor die.

More details and aspects of the ADPLL are mentioned in connection with the proposed concept or one or more examples described above or below (e.g., FIG. 1a to 7b, 9 to 11). The ADPLL may comprise one or more additional optional features corresponding to one or more aspects of the proposed concept or one or more examples described above or below.

Another, more detailed example of an ADPLL 900 is shown in FIG. 9. In the ADPLL shown in FIG. 9, a summation component 901 is provided with a frequency control word (FCW). The summation component 901, in turn provides an integer part to an adder 902 and a fractional part φ_{frac} to a TAU calibration circuit 915 and to a TAU (including an interface and control circuitry) 910. An oscillator 945 is used to provide a digital reference signal FREFD 940 to the TAU. The output of a digital controlled oscillator DCO 935, digital variable clock signal CKVD 930, is also provided as input to the TAU 910. CKVD and FREFD are used as time-mode input signal for the TAU. The fractional part and an output of the TAU calibration circuit are provided as control signals to the TAU. The time-mode output signal of the TAU, CMP_P and CMP_N, are provided as input to a TDC 920. A transfer function of the TAU is defined as Δtₒᵤₜ=G_{TA}·(1−φ_{frac})·T_{CKV}−Δtₛ). The output of the TDC is provided to the TAU calibration circuit 915 and to the adder 902. The CKVD is further provided to a further summation component 904, with an output of the summation component 904 being provided to a sample/hold circuit 905, and with an output of the sample/hold circuit being provided to the adder 902. The output of the adder 902 is provided to a digital loop filter 903, and the output of the digital loop filter 903 is provided to the DCO. The TAU is used to capture an offset, Δtₛ between signal flanks of CKVD and FREFD, thereby generating Δtₒᵤₜ, which is provided to the TDC. The integer part of the FCW and the integer part of the CKVD period counter, provided by summation component 901 and summation component 904 and sample/hold circuit 905, respectively, are only active if the PLL still has to be frequency-locked. After the PLL is locked, these components are switched off, and only the fractional error control loop portion of the ADPLL (including the TAU) remains active, since the error should now be small. In other words, once the PLL is locked, there is no need for the integer phase error portion of the ADPLL to operate, which may save power when the respective portion of the circuit is switched off.

Besides ADPLLs, the proposed TAU circuit arrangement can also find applications in broad areas, such as reference time generation, filter for time signal, analog low power and medium accuracy computation and so on.

More details and aspects of the ADPLL are mentioned in connection with the proposed concept or one or more examples described above or below (e.g., FIG. 1a to 8, 10 to 11). The ADPLL may comprise one or more additional optional features corresponding to one or more aspects of the proposed concept or one or more examples described above or below.

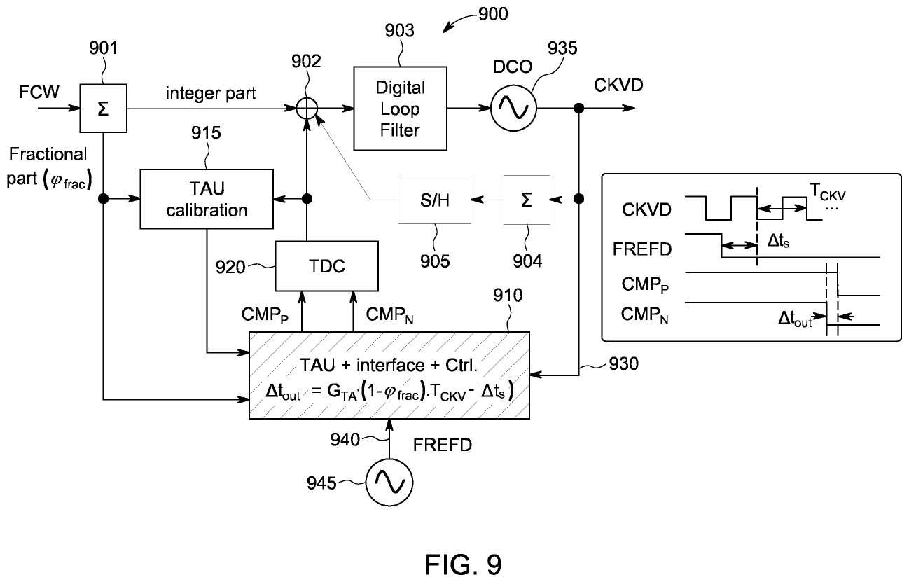

FIG. 10 shows a flow chart of an example of a method for operating a circuit arrangement. For example, the method may be used to operate the (time-register) circuit arrangement/SDU shown in connection with FIGS. 4a to 5b. Features introduced in connection with the (time-register) circuit arrangement/SDU of FIGS. 4a to 5b may be likewise introduced into the corresponding method of FIG. 10.

The method comprises discarding 1010 charges from a capacitive circuit element of the circuit arrangement based on a width of one or more signal pulses of an input signal being provided to the circuit arrangement. The rate at which the charges are discarded is dependent on at least one control signal being provided to the circuit arrangement. The method comprises providing 1020 an output signal flank having a delay relative to a readout signal flank being provided to the circuit arrangement. The delay is based on the charges stored in the capacitive circuit element at the time the readout signal flank is provided to the circuit arrangement.

More details and aspects of the method are mentioned in connection with the proposed concept or one or more examples described above or below (e.g., FIG. 1a to 9, 11). The method may comprise one or more additional optional features corresponding to one or more aspects of the proposed concept or one or more examples described above or below.

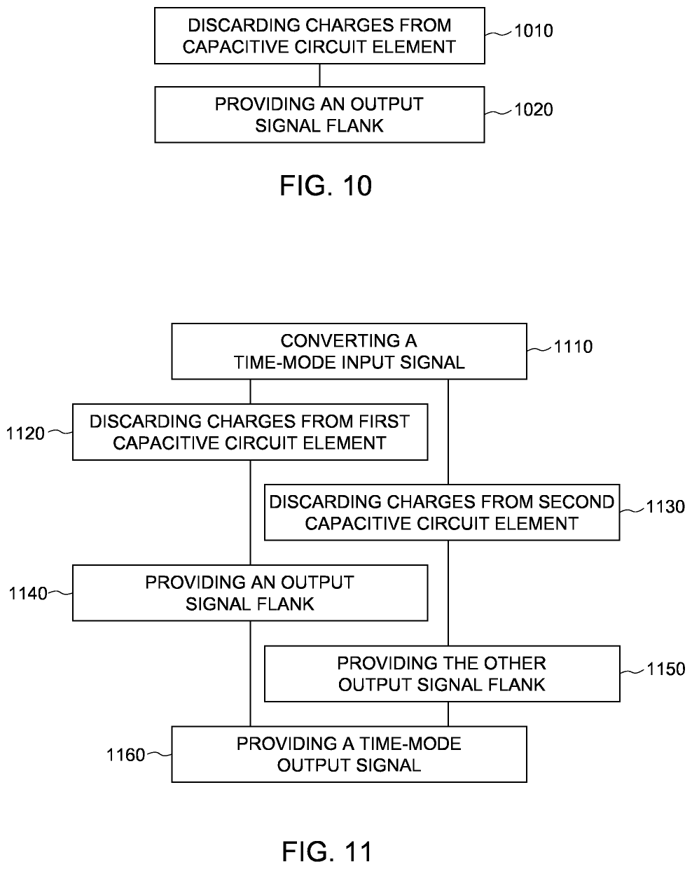

FIG. 11 shows a flow chart of an example of a method for operating a TAU circuit arrangement. For example, the method may be used to operate the TAU circuit arrangement shown in connection with FIGS. 6a to 7b. Features introduced in connection with the TAU circuit arrangement of FIGS. 6a to 7b, and or with the (time-register) circuit arrangement/SDU of FIGS. 4a to 5b, may be likewise introduced into the corresponding method of FIG. 11.

The method comprises converting 1110 a time-mode input signal comprising at least a first pair of input signal flanks to a first and a second input signal. The first and second input signals each comprise at least a first signal pulse having a pulse width being based on a delay between the flanks of the first pair of input signal flanks. The method comprises discarding 1120 charges from a first capacitive circuit element based on a width of at least the first pulse of the first input signal. The method comprises discarding 1130 charges from a second capacitive circuit element based on a width of at least the first pulse of the second input signal. The method comprises providing 1140 a flank of a pair of output signal flanks having a delay relative to a readout signal flank. The delay is based on the charges stored in the first capacitive circuit element at the time the readout signal flank is provided. The method comprises providing 1150 the other flank of the pair of output signal flanks having a delay relative to the readout signal flank. The delay is based on the charges stored in the second capacitive circuit element at the time the readout signal flank is provided. The method comprises providing 1160 a time-mode output signal comprising the pair of output signal flanks.

More details and aspects of the method are mentioned in connection with the proposed concept or one or more examples described above or below (e.g., FIG. 1a to 10). The method may comprise one or more additional optional features corresponding to one or more aspects of the proposed concept or one or more examples described above or below.

In the present disclosure, a concept for a TAU is introduced, providing a major building block for time-mode circuits. While time-mode circuits are not as mature as VMCs or CMCs, the proposed TAU can provide a step towards maturity for TMCs. In general, TMCs may benefit from the proposed TAU in the following aspects.

Firstly, from the functional perspective, the proposed TAU may provide a fast and easy way to design the time-mode counterpart for most analog front-end circuits. As will be introduced in the present disclosure, time-mode analog systems usually lack front-end circuits like filters and Variable Gain Amplifiers (VGAs). This may impose high requirements on TDCs (Time-to-Digital-Converters) and add additional complexity in the overall system design. This challenge can be addressed by using a TAU.

For instance, the transfer function of the proposed TAU (Equation (1) is already in the form of an n-th order FIR filter (Finite Impulse Response) thus, time-mode filters can easily be designed using the proposed TAU. In other words, examples provide an implementation of a filter using the TAU circuit arrangement. Additionally, a time amplification (TA) can be realized elegantly with the proposed TAU by choosing iₒᵤₜ≈τᵢ (e.g., τₒᵤₜ>τᵢ) for all i. This can be used to reduce the requirements on the following TDC being used to quantize the time-mode signal. Furthermore, a variable time-mode signal amplification can be designed by varying the TA factor of TAU τₒᵤₜ/τ₁ for the case n=1.

Secondly, from the performance point of view, the proposed TAU may enable a reduced PVT sensitivity compared to other time-mode circuits, since Δtₒᵤₜ might not depend on PVT-sensitive physical parameters (e.g., supply voltage, transistors threshold voltage, etc.), instead (only) depending on the RC time constants and the discharge pulse duration. This may reduce the calibration effort, system complexity and start-up latency. Especially the latter point is valuable for devices such as IoT wake-up radios, since the wake-up time is heavily influenced by the required start-up calibration duration. If strong non-linearities are present in the system, it may be difficult to achieve a good calibration accuracy. In such cases, PVT robustness is also beneficial. Since the output of the proposed TAU can be implemented to be independent of voltage levels, the required rejection of power supply fluctuations may also be greatly reduced. Furthermore, due to the differential structure, distortions caused by the circuit may cancel at the output if both paths are identical.

For the same reason, if the proposed TAU is utilized to implement a DTC, the PVT immunity (sensitivity) can also be greatly improved compared to other DTCs. Furthermore, TAU-based DTCs may represent a balanced approach between noisy constant slope DTCs and non-linear variable slope DTCs, i.e., a TAU-based DTC may offer lower noise compared to a constant slope DTC and better linearity compared to a variable slope DTC. A TAU-based DTC may also have less complexity in terms of biasing compared to a constant slope DTC, since generating an area efficient low-noise low-power constant current is challenging on-chip.

Various examples may also improve linearity. Due to an improved immunity to supply fluctuation, TAU-based DTCs may have a less-pronounced memory effect. This may result in a better system linearity and less complexity in the power supply design compared to other DTC structures.

The aspects and features described in relation to a particular one of the previous examples may also be combined with one or more of the further examples to replace an identical or similar feature of that further example or to additionally introduce the features into the further example. Various examples provide:
(1) A circuit arrangement configured to:
   discard charges from a capacitive circuit element of the circuit arrangement based on a width of one or more signal pulses of an input signal being provided to the circuit arrangement, with the rate at which the charges are discarded being dependent on at least one control signal being provided to the circuit arrangement; and
   provide an output signal flank having a delay relative to a readout signal flank being provided to the circuit arrangement, with the delay being based on the charges stored in the capacitive circuit element at the time the readout signal flank is provided to the circuit arrangement.
(2) The circuit arrangement according to (1), wherein the capacitive circuit element is a tunable capacitive circuit element.
(3) The circuit arrangement according to (2), wherein the circuit arrangement is configured to vary the rate at which the charges are discarded by controlling a capacitance of the tunable capacitive circuit element based on the at least one control signal.
(4) The circuit arrangement according to one of (1) to (3), wherein the capacitive circuit element comprises a capacitor bank.
(5) The circuit arrangement according to one of (1) to (4), wherein the charges are discarded via a resistive circuit element of the circuit arrangement.
(6) The circuit arrangement according to (5), wherein the resistive circuit element is a tunable resistive circuit element.
(7) The circuit arrangement according to (6), wherein the circuit arrangement is configured to vary the rate at which the charges are discarded by controlling an electrical resistance of the tunable resistive element based on the at least one control signal.
(8) The circuit arrangement according to one of (5) to (7), wherein the resistive circuit element comprises a resistor bank.
(9) The circuit arrangement according to one of (1) to (8), comprising an output circuit element, wherein the output circuit element is configured to provide the output signal flank having the delay relative to the readout signal.
(10) The circuit arrangement according to (9), wherein the circuit arrangement is configured to discard the charges remaining in the capacitive circuit element in response to the readout signal flank, wherein the output circuit element is a comparator circuit, configured to trigger the output signal flank when a voltage representing the charges remaining in the capacitive circuit element reaches a voltage threshold.
(11) The circuit arrangement according to one of (1) to (10), wherein the circuit arrangement is implemented in a semiconductor die.
(12) A Time-mode Arithmetic Unit, TAU, circuit arrangement, comprising:
   at least a first and a second circuit arrangement according to one of (1) to (11); and
   control circuitry configured to:
   convert a time-mode input signal comprising at least a first pair of input signal flanks to a first and a second input signal, the first and second input signal each comprising at least a first signal pulse having a pulse width being based on a delay between the flanks of the first pair of input signal flanks,
   provide the first and second input signal to the first and second circuit arrangement, and provide a time-mode output signal comprising a pair of output signal flanks based on respective output signals of the first and second circuit arrangements.
(13) The TAU circuit arrangement according to (12), wherein the control circuitry is configured to provide, if the time-mode input signal further comprises at least one further pair of input signal flanks, each of the first and second input signals with at least one further signal pulse having a pulse width being based on a delay between the signal flanks of the at least one further pair of input signal flanks.
(14) The TAU circuit arrangement according to (13), wherein the TAU circuit arrangement is configured to perform a time-mode summation of the delay between the signal flanks of the first pair of input signal flanks and the delay between the signal flanks of the at least one further pair of input signal flanks, with the delay between the pair of output signal flanks representing the result of the time-mode summation.
(15) The TAU circuit arrangement according to one of (12) to (14), wherein the control circuitry is configured to provide at least one control signal to the first and second circuit arrangement, the at least one control signal being configured to control the rate at which charges are being discarded from a capacitive circuit element of the respective circuit arrangements.
(16) The TAU circuit arrangement according to (15), wherein the control circuitry is configured to provide the control signal during at least a first time interval and a final time interval, the first time interval encompassing the first signal pulses being provided as part of the first and second input signal and the final time interval encompassing a time between the readout signal flank and the provision of the pair of output signal flanks of the output signal.
(17) The TAU circuit arrangement according to (16), wherein the control circuitry is configured to provide the control signal further during at least one further time interval between the first and the final time interval, the at least one further time interval encompassing at least one further signal pulse being provided as part of each of the first and second input signal.
(18) The TAU circuit arrangement according to (17), wherein the control circuitry is configured to update the control signal for each of the first time interval, the at least one further time interval and the final time interval.
(19) The TAU circuit arrangement according to one of (17) or (18), wherein the control signal provided during the first and at least one further time intervals acts as weighting factor, influencing the amount of charges being discarded in response to the first and at least one further signal pulses included in the first and second input signal.
(20) The TAU circuit arrangement according to (19), wherein the TAU circuit arrangement is configured to perform a time-mode weighted summation of the delay between the signal flanks of the first pair of input signal flanks and the delay between the signal flanks of the at least one further pair of input signal flanks, weighted by the weighting factor, with the delay between the pair of output signal flanks representing the result of the time-mode weighted summation.
(21) The TAU circuit arrangement according to one of (15) to (20), wherein the control circuitry is configured to update the control signal for the final time interval such, that the rate, at which charges are being discarded from the capacitive circuit element of the respective circuit arrangements, is set according to a scaling control signal, with the rate at which charges are being discarded from the capacitive circuit element of the respective circuit elements during the final time interval being settable to be smaller than, equal to, and greater than the rate at which charges are being discarded from the capacitive circuit element of the respective circuit elements during the first time interval via the scaling control signal.
(22) The TAU circuit arrangement according to one of (15) to (21), wherein the control signal provided during the final time interval acts as scaling factor, influencing a time delay between the pair of output signal flanks.
(23) The TAU circuit arrangement according to (22), wherein the TAU circuit arrangement is configured to perform a time-mode summation of the delay between the signal flanks of the first pair of input signal flanks and the delay between the signal flanks of the at least one further pair of input signal flanks, with the delay between the pair of output signal flanks representing the result of the time-mode summation, multiplied by the scaling factor.
(24) The TAU circuit arrangement according to one of (15) to (23), wherein the control circuitry is configured to provide the at least one control signal such, that the rate at which charges are being discarded from the capacitive circuit element is the same for the first and second circuit arrangement.
(25) The TAU circuit arrangement according to one of (12) to (24), wherein the first signal pulse of the first input signal has a pulse width being different from a pulse width of the first signal pulse of the second input signal if the delay between the signal flanks of the first pair of input signal flanks is greater than zero.
(26) The TAU circuit arrangement according to one of (12) to (25), wherein the control circuitry is configured to switch between generating signal pulses having a wider pulse width for the first input signal and generating signal pulses having a wider pulse width for the second input signal based on a sign setting signal being provided to the TAU circuit arrangement.
(27) The TAU circuit arrangement according to (26), wherein the TAU circuit arrangement is configured to perform a time-mode summation of the delay between the flanks of the first pair of input signal flanks and the delay between flanks of at least one further pair of input signal flanks, with the sign setting signal being used to select between a summand being positive or negative, and with the pair of output signal flanks representing the result of the time-mode summation.
(28) The TAU circuit arrangement according to one of (12) to (27), wherein the control circuitry comprises a phase frequency detector circuitry for converting the time-mode input signal to the first and second input signal, thereby converting signal flanks to pulse widths.
(29) The TAU circuit arrangement according to one of (12) to (28), wherein the TAU circuit arrangement is implemented in a semiconductor die.
(30) An All-Digital Phase-Locked Loop circuit arrangement comprising the TAU circuit arrangement according to one of (12) to (29).
(31) The ADPLL circuit arrangement according to (30), wherein the TAU circuit arrangement is configured to capture an offset between an oscillator signal and a signal flank of a reference signal of the ADPLL circuit arrangement.
(32) The ADPLL circuit arrangement according to one of (30) or (31), comprising the TAU circuit arrangement according to one of (22) or (23), wherein the scaling factor is used to scale the delay between the pair of output signal flanks for a Time to Digital Converter of the ADPLL circuit arrangement.
(33) The ADPLL circuit arrangement according to one of (30) to (32), wherein the ADPLL circuit arrangement is implemented in a semiconductor die.
(34) A circuit arrangement comprising a capacitive circuit element, a resistive circuit element and an output circuit element,
   wherein the circuit arrangement is configured to discard charges from the capacitive circuit element via the resistive circuit element based on a width of one or more signal pulses of an input signal being provided to the circuit arrangement,
   wherein the rate at which the charges are discarded via the resistive circuit element are dependent on at least one control signal being provided to the circuit arrangement to control at least one of a capacitance of the capacitive circuit element and an electrical resistance of the resistive circuit element, and
   wherein the output circuit element is configured to provide an output signal flank having a delay relative to a readout signal flank being provided to the circuit arrangement, with the delay being based on the charges stored in the capacitive circuit element at the time the readout signal flank is provided to the circuit arrangement.
(35) A method for operating a circuit arrangement, the method comprising:
   discarding charges from a capacitive circuit element of the circuit arrangement based on a width of one or more signal pulses of an input signal being provided to the circuit arrangement, with the rate at which the charges are discarded being dependent on at least one control signal being provided to the circuit arrangement; and
   providing an output signal flank having a delay relative to a readout signal flank being provided to the circuit arrangement, with the delay being based on the charges stored in the capacitive circuit element at the time the readout signal flank is provided to the circuit arrangement.
(36) A method for operating a Time-mode Arithmetic Unit, TAU, circuit arrangement, comprising:
   converting a time-mode input signal comprising at least a first pair of input signal flanks to a first and a second input signal, the first and second input signals each comprising at least a first signal pulse having a pulse width being based on a delay between the flanks of the first pair of input signal flanks;
   discarding charges from a first capacitive circuit element based on a width of at least the first pulse of the first input signal;
   discarding charges from a second capacitive circuit element based on a width of at least the first pulse of the second input signal;
   providing a flank of a pair of output signal flanks having a delay relative to a readout signal flank, with the delay being based on the charges stored in the first capacitive circuit element at the time the readout signal flank is provided;
   providing the other flank of the pair of output signal flanks having a delay relative to the readout signal flank, with the delay being based on the charges stored in the second capacitive circuit element at the time the readout signal flank is provided;
   providing a time-mode output signal comprising the pair of output signal flanks.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A circuit arrangement configured to:
discard charges from a capacitive circuit element of the circuit arrangement based on a width of one or more signal pulses of an input signal being provided to the circuit arrangement, with the rate at which the charges are discarded being dependent on at least one control signal being provided to the circuit arrangement; and
provide an output signal flank having a delay relative to a readout signal flank being provided to the circuit arrangement, with the delay being based on the charges stored in the capacitive circuit element at the time the readout signal flank is provided to the circuit arrangement.

2. The time-register circuit arrangement according to claim 1, wherein the capacitive circuit element is a tunable capacitive circuit element, wherein the circuit arrangement is configured to vary the rate at which the charges are discarded by controlling a capacitance of the tunable capacitive circuit element based on the at least one control signal.

3. The circuit arrangement according to claim 1, wherein the charges are discarded via a resistive circuit element of the circuit arrangement.

4. The circuit arrangement according to claim 3, wherein the resistive circuit element is a tunable resistive circuit element, wherein the circuit arrangement is configured to vary the rate at which the charges are discarded by controlling an electrical resistance of the tunable resistive element based on the at least one control signal.

5. The circuit arrangement according to claim 4, comprising an output circuit element, wherein the output circuit element is configured to provide the output signal flank having the delay relative to the readout signal.

6. The circuit arrangement according to claim 5, wherein the circuit arrangement is configured to discard the charges remaining in the capacitive circuit element in response to the readout signal flank, wherein the output circuit element is a comparator circuit, configured to trigger the output signal flank when a voltage representing the charges remaining in the capacitive circuit element reaches a voltage threshold.

7. A Time-mode Arithmetic Unit, TAU, circuit arrangement, comprising:
at least a first and a second circuit arrangement according to claim 1; and
control circuitry configured to:
convert a time-mode input signal comprising at least a first pair of input signal flanks to a first and a second input signal, the first and second input signal each comprising at least a first signal pulse having a pulse width being based on a delay between the flanks of the first pair of input signal flanks,
provide the first and second input signal to the first and second circuit arrangement, and
provide a time-mode output signal comprising a pair of output signal flanks based on respective output signals of the first and second circuit arrangements.

8. The TAU circuit arrangement according to claim 7, wherein the control circuitry is configured to provide, if the time-mode input signal further comprises at least one further pair of input signal flanks, each of the first and second input signals with at least one further signal pulse having a pulse width being based on a delay between the signal flanks of the at least one further pair of input signal flanks.

9. The TAU circuit arrangement according to claim 8, wherein the TAU circuit arrangement is configured to perform a time-mode summation of the delay between the signal flanks of the first pair of input signal flanks and the delay between the signal flanks of the at least one further pair of input signal flanks, with the delay between the pair of output signal flanks representing the result of the time-mode summation.

10. The TAU circuit arrangement according to claim 7, wherein the control circuitry is configured to provide at least one control signal to the first and second circuit arrangement, the at least one control signal being configured to control the rate at which charges are being discarded from a capacitive circuit element of the respective circuit arrangements.

11. The TAU circuit arrangement according to claim 10, wherein the control circuitry is configured to provide the control signal during at least a first time interval and a final time interval, the first time interval encompassing the first signal pulses being provided as part of the first and second input signal and the final time interval encompassing a time between the readout signal flank and the provision of the pair of output signal flanks of the output signal.

12. The TAU circuit arrangement according to claim 11, wherein the control circuitry is configured to provide the control signal further during at least one further time interval between the first and the final time interval, the at least one further time interval encompassing at least one further signal pulse being provided as part of each of the first and second input signal.

13. The TAU circuit arrangement according to claim 12, wherein the control signal provided during the first and at least one further time intervals acts as weighting factor, influencing the amount of charges being discarded in response to the first and at least one further signal pulses included in the first and second input signal.

14. The TAU circuit arrangement according to claim 13, wherein the TAU circuit arrangement is configured to perform a time-mode weighted summation of the delay between the signal flanks of the first pair of input signal flanks and the delay between the signal flanks of the at least one further pair of input signal flanks, weighted by the weighting factor, with the delay between the pair of output signal flanks representing the result of the time-mode weighted summation.

15. The TAU circuit arrangement according to claim 11, wherein the control signal provided during the final time interval acts as scaling factor, influencing a time delay between the pair of output signal flanks, wherein the TAU circuit arrangement is configured to perform a time-mode summation of the delay between the signal flanks of the first pair of input signal flanks and the delay between the signal flanks of the at least one further pair of input signal flanks, with the delay between the pair of output signal flanks representing the result of the time-mode summation, multiplied by the scaling factor.

16. The TAU circuit arrangement according to claim 7, wherein the control circuitry is configured to switch between generating signal pulses having a wider pulse width for the first input signal and generating signal pulses having a wider pulse width for the second input signal based on a sign setting signal being provided to the TAU circuit arrangement.

17. An All-Digital Phase-Locked Loop, ADPLL, circuit arrangement comprising the TAU circuit arrangement according to claim 7.

18. The ADPLL circuit arrangement according to claim 17, wherein the TAU circuit arrangement is configured to capture an offset between an oscillator signal and a signal flank of a reference signal of the ADPLL circuit arrangement.

19. A method for operating a circuit arrangement, the method comprising:
discarding charges from a capacitive circuit element of the circuit arrangement based on a width of one or more signal pulses of an input signal being provided to the circuit arrangement, with the rate at which the charges are discarded being dependent on at least one control signal being provided to the circuit arrangement; and
providing an output signal flank having a delay relative to a readout signal flank being provided to the circuit arrangement, with the delay being based on the charges stored in the capacitive circuit element at the time the readout signal flank is provided to the circuit arrangement.

20. A method for operating a Time-mode Arithmetic Unit, TAU, circuit arrangement, comprising:
converting a time-mode input signal comprising at least a first pair of input signal flanks to a first and a second input signal, the first and second input signals each comprising at least a first signal pulse having a pulse width being based on a delay between the flanks of the first pair of input signal flanks;
discarding charges from a first capacitive circuit element based on a width of at least the first pulse of the first input signal;
discarding charges from a second capacitive circuit element based on a width of at least the first pulse of the second input signal;
providing a flank of a pair of output signal flanks having a delay relative to a readout signal flank, with the delay being based on the charges stored in the first capacitive circuit element at the time the readout signal flank is provided;
providing the other flank of the pair of output signal flanks having a delay relative to the readout signal flank, with the delay being based on the charges stored in the second capacitive circuit element at the time the readout signal flank is provided;
providing a time-mode output signal comprising the pair of output signal flanks.
